(19) United States
(12) Patent Application Publication
(10) Pub. No.: US 2007/0266293 A1
(43) Pub. Date: Nov. 15, 2007

(54) Apparatus and method for high speed data transceiving, and apparatus and method for error-correction processing for the same

(75) Inventor: Ki-bo Kim, Suwon-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD., Suwon-si (KR)

(21) Appl. No.: 11/707,029

(22) Filed: Feb. 16, 2007

Related U.S. Application Data
(60) Provisional application No. 60/799,027, filed on May 10, 2006.

(30) Foreign Application Priority Data
Sep. 8, 2006 (KR) 10-2006-0086964

(51) Int. Cl. H03M 13/00

(52) U.S. Cl. 714/752

(57) ABSTRACT

An apparatus and a method for high-speed data transceiving, and an apparatus and a method for error-correction processing for the same are provided. The high speed data transmitting apparatus includes an error-correction coding unit which performs error-correction coding of input data in parallel, and a radio-transmitting unit which processes the input data which has been error-correction coded by the error-correction coding unit and outputs the input data which has been processed to a wireless medium.

### CROSS-REFERENCE TO RELATED APPLICATION

This application is based on and claims priority from Korean Patent Application No. 10-2006-0086964 filed in the Korean Intellectual Property Office on Sep. 8, 2006 and U.S. Provisional Application No. 60/799,027 filed on May 10, 2006 in the United States Patent and Trademark Office, the disclosures of which are incorporated herein in their entirety by reference.

### BACKGROUND OF THE INVENTION

1. Field of the Invention

Apparatuses and methods consistent with the present invention relate to wireless communication, and more particularly, to a high-speed data-transceiving apparatus and a high speed data-transceiving method for increasing the data processing speed, and an error-correction-processing apparatus and an error-correction processing method for implementing the same.

2. Description of the Related Art

Networks are becoming wireless, demands for high capacity multimedia data transmission are increasing, and research is required to develop effective transmission methods in a wireless network environment. Moreover, the desire to wirelessly transmit high quality video, such as a Digital Video Disk (DVD) image, a High Definition Television (HDTV) image, and others, between various home devices is increasing.

Currently, an IEEE 802.15.3c task group is promoting the adoption of a technical standard for transmitting high capacity data in a wireless home network. In such a standard, called mmWave (Millimeter Wave), a radio wave having a wavelength on the order of millimeters (that is, a radio wave with a frequency of 30 GHz to 300 GHz) is used for high capacity data transmission. Up to now, this frequency band has been treated as an unlicensed band, and its use has been limited to communication providers, radio astronomy, vehicle collision avoidance and so forth.

The IEEE 802.11b or the IEEE 802.11g employs a carrier frequency of 2.4 GHz and a channel bandwidth of about 20 MHz. Also, the IEEE 802.11a or the IEEE 802.11n employs a carrier frequency of 5 GHz and a channel bandwidth of about 20 MHz. In contrast, the mmWave uses a carrier frequency of 60 GHz, and has a channel bandwidth of 0.5 to 2.5 GHz. Thus, the carrier frequency and the channel bandwidth of the mmWave are much larger than those of existing IEEE 802 standards. If a high frequency signal with a millimeter wavelength (mmWave) is used in this way, a very high data rate on the order of several gigabits per second (Gbps) can be obtained, and a single chip including an antenna can be realized because the size of an antenna can be reduced to below 1.5 mm.

Particularly, research has recently been pursued to transmit uncompressed audio and/or video (AV) data between wireless appliances by using the high bandwidth of mmWave. Compressed AV data is loss-compressed in such a manner that portions that the human visual and auditory system are less sensitive to are removed through processes of motion compensation, discrete cosine transform (DCT) transform, quantization, variable length coding, and others. Thus, in the case of the compressed AV data, deterioration of image quality may be caused by the compensation loss, and there is a problem in that AV data compression and restoration operations must follow the same standard. On the contrary, since the uncompressed AV data contains digital values representing pixel components (e.g., R, G and B components) in their entirety, it can advantageously provide sharper image quality.

Data must pass through various signal processing operations, such as scrambling, Forward Error Correction (FEC) coding, interleaving, modulation and the like, before being transmitted over a wireless medium. In order to transmit uncompressed AV data, the amount of which is huge, over a wireless medium, it is necessary to pay attention to the design of a transceiver system. This is because if various signal processing operations for huge uncompressed AV data are not completed in time, it is impossible to transmit the uncompressed AV data. Particularly, since error-correction coding, which occupies a very important position in high quality AV data transmission, requires an amount of operations, it can be said that technology for reducing the operation time of FEC coding is requisite for transmitting uncompressed AV data. Therefore, there is a need for technology to efficiently transmit high capacity data such as uncompressed AV data.

### SUMMARY OF THE INVENTION

Exemplary embodiments of the present invention overcome the above disadvantages and other disadvantages not described above. Also, the present invention is not required to overcome the disadvantages described above, and an exemplary embodiment of the present invention may not overcome any of the problems described above.

The present invention is provides a high-speed data-transceiving apparatus and a high speed data-transceiving method for increasing the data processing speed, and an error-correction-processing apparatus and an error-correction processing method for implementing the same.

In accordance with an aspect of the present invention, there is provided an apparatus for high-speed data transmission, the apparatus including an error-correction coding unit performing in parallel error-correction coding for first input data; and a radio-transmitting unit processing the error-correction coded first input data and outputting the processed first input data to a wireless medium.

In accordance with another aspect of the present invention, there is provided an apparatus for error-correction coding, the apparatus including a demultiplexing unit splitting input data into a plurality of data groups; and a plurality of sub error-correction coding units performing error-correction coding independently for each of the plurality of data groups.

In accordance with yet another aspect of the present invention, there is provided an apparatus for error-correction coding, the apparatus including at least one or more outer encoders performing outer encoding for one or more data groups constituting input data; and a plurality of inner encoders performing inner encoding for at least one of the data groups outer encoded by one or more outer encoders.

In accordance with still yet another aspect of the present invention, there is provided a method of high speed data transmission, the method including performing in parallel error-correction coding for first input data; and processing the error-correction coded first input data and outputting the processed first input data to a wireless medium.

In accordance with still yet another aspect of the present invention, there is provided a method of error-correction coding, the method including splitting input data into a plurality of data groups; and performing error-correction coding independently for each of the plurality of data groups.

In accordance with still yet another aspect of the present invention, there is provided a method of error-correction coding, the method including splitting input data into a plurality of first data groups and performing outer encoding for each of the plurality of first data groups; and splitting each of the outer encoded first data groups into a plurality of second data groups and performing inner encoding for each of the plurality of second data groups.

In accordance with still yet another aspect of the present invention, there is provided a method of error-correction coding, the method including performing RS encoding for a plurality of data groups constituting input data; and performing inner encoding independently for each of the plurality of RS encoded data groups.

In accordance with still yet another aspect of the present invention, there is provided an apparatus for radio reception, the apparatus including a radio-receiving unit extracting given data from a signal received over a wireless medium; and an error-correction-decoding unit performing in parallel error correction decoding for the extracted data.

In accordance with still yet another aspect of the present invention, there is provided a method of radio reception, the method including extracting given data from a signal received over a wireless medium; and performing in parallel error correction decoding for the extracted data.

In accordance with still yet another aspect of the present invention, there is provided an apparatus for error correction decoding, the apparatus including a demultiplexing unit splitting input data into a plurality of data groups; and a plurality of error-correction-decoding units performing error correction decoding independently for each of the plurality of split data groups.

In accordance with still yet another aspect of the present invention, there is provided a method of error correction decoding, the method including splitting input data into a plurality of data groups; and performing error correction decoding independently for each of the plurality of split data groups.

### BRIEF DESCRIPTION OF THE DRAWINGS

The above and other aspects of the present invention will be more apparent from the following detailed description of exemplary embodiments taken in conjunction with the accompanying drawings, in which:

FIG. 1 is a block diagram illustrating a radio-transmitting apparatus in accordance with an exemplary embodiment of the present invention;

FIG. 2 is a block diagram illustrating a scrambler in accordance with an exemplary embodiment of the present invention;

FIG. 3 is a block diagram illustrating an error-correction coding procedure in accordance with an exemplary embodiment of the present invention;

FIG. 4 is a block diagram illustrating a sub error-correction coding unit in accordance with an exemplary embodiment of the present invention;

FIG. 5 is a block diagram illustrating a convolution encoder in accordance with an exemplary embodiment of the present invention;

FIG. 6 is a diagram illustrating bit strings input into and output from the convolution encoder in FIG. 5;

FIG. 7 is a diagram illustrating a result of puncturing in accordance with an exemplary embodiment of the present invention;

FIG. 8 is a block diagram illustrating an error-correction coding unit in accordance with an exemplary embodiment of the present invention;

FIG. 9 is a block diagram illustrating an error-correction coding unit in accordance with another exemplary embodiment of the present invention;

FIG. 10 is a block diagram illustrating an error-correction coding unit in accordance with yet another embodiment of the present invention;

FIG. 11 is a diagram illustrating an interleaving procedure in accordance with an exemplary embodiment of the present invention;

FIG. 12 is a block diagram illustrating an error-correction coding unit in accordance with still another exemplary embodiment of the present invention;

FIG. 13 is a block diagram illustrating an error-correction coding unit in accordance with yet another exemplary embodiment of the present invention;

FIG. 14 is a block diagram illustrating an error-correction coding unit in accordance with still another exemplary embodiment of the present invention;

FIG. 15 is a block diagram illustrating an error-correction coding unit in accordance with yet another exemplary embodiment of the present invention;

FIGS. 16A to 16C are views illustrating QAM mapping tables in accordance with exemplary embodiments of the present invention;

FIG. 17 is a block diagram illustrating a radio-transmitting apparatus in accordance with another exemplary embodiment of the present invention;

FIG. 18 is a flowchart illustrating a radio-transmitting method for high-speed data transmission in accordance with an exemplary embodiment of the present invention;

FIG. 19 is a block diagram illustrating a radio-receiving apparatus in accordance with an exemplary embodiment of the present invention;

FIG. 20 is a block diagram illustrating an error-correction-decoding unit in accordance with an exemplary embodiment of the present invention; and

FIG. 21 is a flowchart illustrating a radio-receiving method for high-speed data transmission.

### DETAILED DESCRIPTION OF THE EXEMPLARY EMBODIMENTS

Advantages and features of the present invention, and ways to achieve them will be apparent from exemplary embodiments of the present invention described with reference to the accompanying drawings in the following. However, the scope of the present invention is not limited to such embodiments and the present invention may be realized in various forms. The embodiments disclosed in the specification are nothing but examples provided to disclose the present invention and assist those skilled in the art to completely understand the present invention. The present invention is defined only by the scope of the appended claims. Also, the same reference numerals are used to designate the same elements throughout the specification and drawings.

Hereinafter, exemplary embodiments of the present invention will be described in detail with reference to the accompanying drawings.

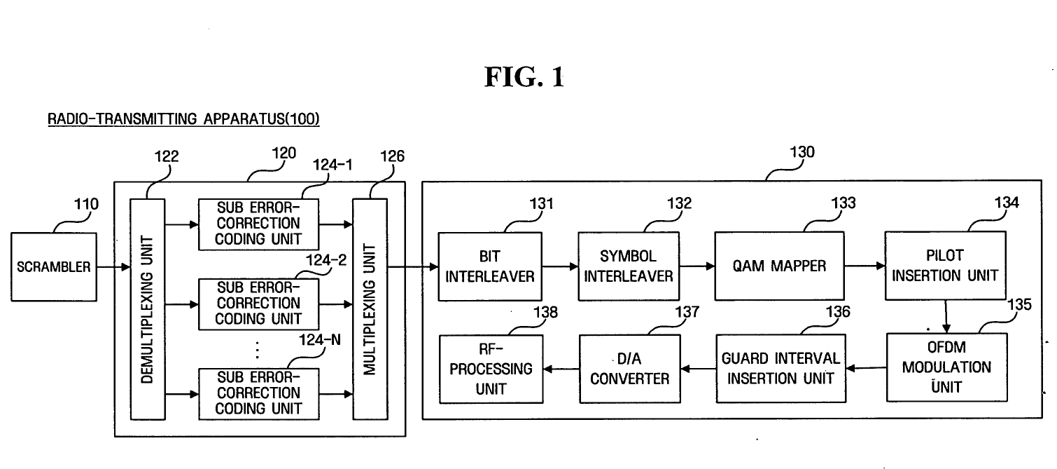

FIG. 1 illustrates a radio-transmitting apparatus 100 according to an exemplary embodiment of the present invention.

The radio-transmitting apparatus 100 illustrated in the drawing includes a scrambler 110, an error-correction coding unit 120 and a radio-transmitting unit 130.

The scrambler 110 scrambles input data. By scrambling data, timing information between a party transmitting a signal and a party receiving the transmitted signal is prevented from being lost, and energy of input data can be distributed over the entire band. According to an exemplary embodiment of the present invention, the scrambler 110 may use a generator polynomial, P(x) expressed by the following equation.

P(x)=x⁷+x⁴+1 (1)

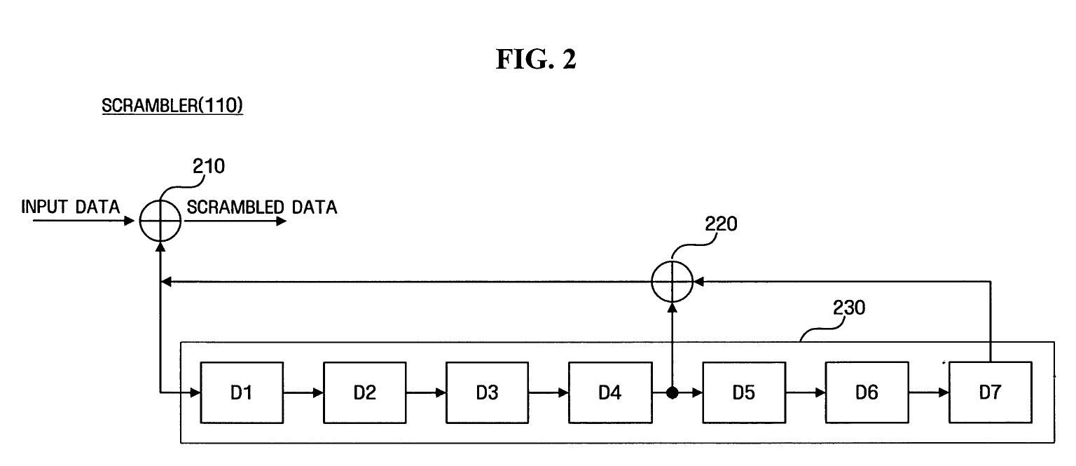

In the case where equation 1 is used, the scrambler 110 may be configured as illustrated in FIG. 2. As shown in FIG. 2, the scrambler 110 includes a shift register 230, a first adder 210 and a second adder 220. The shift register 210 includes seven unit registers D1 to D7. Here, all the unit registers D1 to D7 have an initial value of “1”. Of course, the present invention is not limited to this, and an initial value allocated to the unit registers D1 to D7 may differ in other embodiments. A scrambling operation is performed every data unit, and the unit registers D1 to D7 are reset to an initial value whenever the scrambler 110 starts scrambling for a new data unit. The generator polynomial used by the scrambler 110 and the configuration of the scrambler 110 are not limited to equation 1 and FIG. 2, but may vary according to other embodiments.

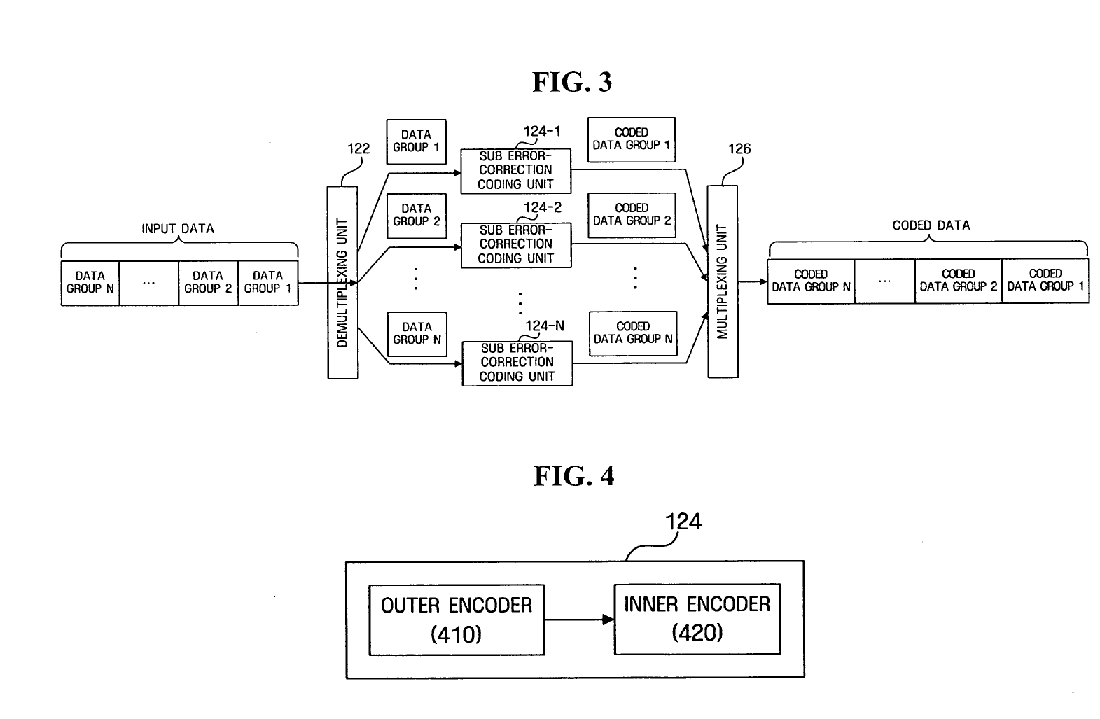

The error-correction coding unit 120 performs error-correction coding of input data in parallel. For example, the error-correction coding unit 120 may split input data into a plurality of data groups and perform error-correction coding at the same time for each of the plurality of data groups. To this end, the error-correction coding unit 120 may include a demultiplexing unit 122, a plurality of sub error-correction coding units 124-1 to 124-N, and a multiplexing unit 126, as illustrated in FIG. 1. In the following description, reference numeral “124” will be used for designating each sub error-correction coding unit 124-1 to 124-N. FIG. 3 illustrates a procedure in which input data is error-correction coded in parallel by the error-correction coding unit 120. Input data is split according to data groups by the demultiplexing unit 122, and the respective split data groups are error-correction coded through the sub error-correction coding units 124. The error-correction coded data groups are combined again into serial coded data by the multiplexing unit 126.

Preferably, but not necessarily, the input data includes data groups, which are appropriately sized such that it is possible for the sub error-correction coding units 124 to perform independent error-correction coding operations. Further, the error-correction coding unit 120 preferably operates based on Forward Error Correction (FEC). In addition, it may be preferable that the number of sub error-correction coding units 124 included in the error-correction coding unit 120 is an even number, more preferably any one of even numbers 2, 4, 6, 8, 10, 12 and 16.

If data groups constituting input data are of the same importance, the same code rate can be used in error-correction coding for the respective data groups. If the importance of different data groups constituting input data, it may be preferable to apply a lower code rate to a data group having higher importance and apply a higher code rate to a data group having lower importance, thereby causing a more important data group to obtain a greater error correction effect. Thus, the respective sub error-correction coding units 124 may use the same code rate all together or use different code rates. It is also possible for a part of the sub error-correction coding units 124 to use the same code rate.

Hereinafter, the error-correction coding unit 120 will be described in more detail with reference to FIGS. 4 to 15.

The sub error-correction coding unit 124 may include an outer encoder 410 and an inner encoder 420, as illustrated in FIG. 4. An error-correction coding algorithm is classified broadly into two types. One of them is characteristically resistant to burst errors, and the other is effective against random errors. These two types of error-correction coding, which have different characteristics, are generally used in connection with each other in order to improve error-correction coding performance. This is called “concatenated coding”. In such concatenated coding, an encoder used for primary encoding (outer encoding) is referred to as the outer encoder 410, and an encoder performing encoding (inner encoding) again after the primary encoding is referred to as the inner encoder 420. In general, the concatenated coding is configured such that the outer encoder 410 uses an algorithm resistant to burst errors and the inner encoder 410 uses an algorithm resistant to random errors. A codeword, which is output as a result of the inner encoding, is usually affected by previous input data as well as current input data.

An exemplary example of the outer encoder 410 includes a Reed-Solomon (RS) encoder using RS codes, a Bose-Chaudhuri-Hocquenghem (BCH) encoder using BCH codes, a Hamming encoder using Hamming codes and the like.

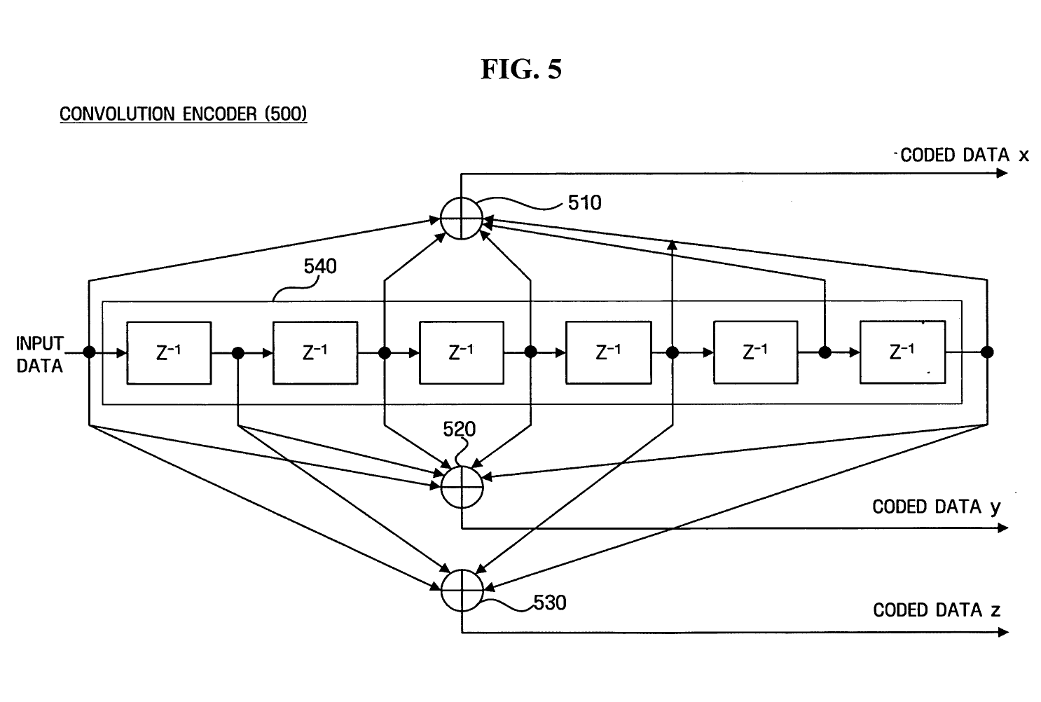

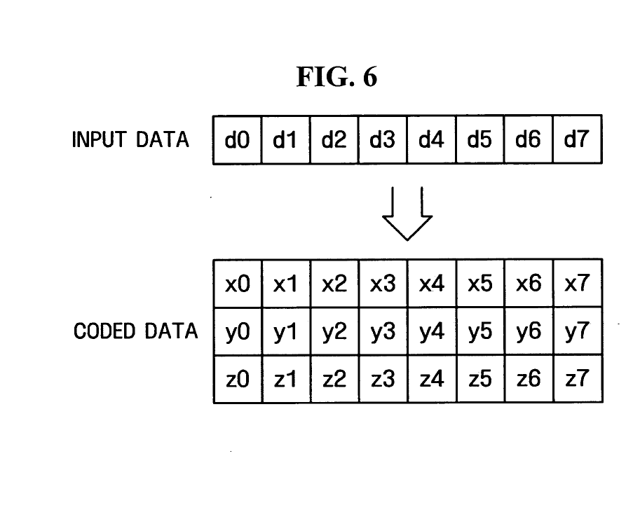

A convolution encoder for performing convolution coding may be used as the inner encoder 420. FIG. 5 illustrates a convolution encoder 500 according to an exemplary embodiment of the present invention. The convolution encoder 500 illustrated in FIG. 5 has a constraint length of 7, six delay memories, generator polynomials of g0=133o, g1=171o and g2=145o, and a basic code rate of 1/3. As illustrated in the drawing, the convolution encoder 500 includes a first adder 510, a second adder 520, a third adder 530 and a delay register 540. An initial value of the delay register 540 may be set to “0”, and the delay register 540 is set to the initial value whenever a new data group is input. Data output from the convolution encoder 500 has three times as many bits as the input data, which is shown in FIG. 6.

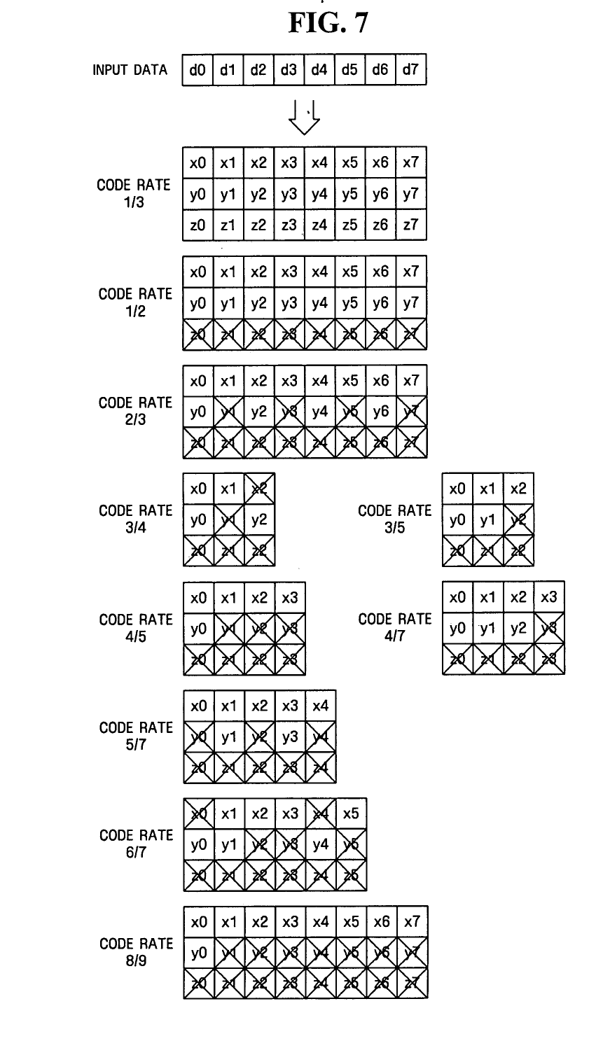

In the case of a convolution encoder, a puncturer for adjusting a code rate may be used together. A code rate may vary with required error correction performance, and a data group, which has been encoded by a convolution encoder, passes through a puncturer in order to adjust a code rate. A code rate according to an exemplary embodiment of the present invention may be any one of 1/3, 1/2, 2/3, 3/4, 3/5, 4/5, 4/7, 5/7, 6/7 and 8/9. FIG. 7 illustrates results of puncturing for providing such code rates. In FIG. 7, “d0 to d1” are bits of input data, and “x0 to x7”, “y0 to y7” and “z0 to z7” are bits of coded data. Bits to be discarded and bits to be output from the coded data may change according to code rates. In the embodiment of FIG. 7, bits to be discarded are marked with “X” so as to discern them from the remaining bits to be output. A puncturing table corresponding to the puncturing results in FIG. 7 is shown in Table 1.

TABLE 1

| Code Rate | Puncturing Pattern | Output Sequence |
|---|---|---|
| ⅓ | X: 1, Y: 1, Z: 1 | X1 Y1 Z1 |
| ½ | X: 1, Y: 1, Z: 0 | X1 Y1 |
| ⅔ | X: 11, Y: 10, Z: 00 | X1 Y1 X2 |
| ¾ | X: 110, Y: 101, Z: 000 | X1 Y1 X2 Y3 |
| ⅗ | X: 111, Y: 110, Z: 000 | X1 Y1 X2 Y2 X3 |
| ⅘ | X: 1111, Y: 1000, Z: 0000 | X1 Y1 X2 X3 X4 |
| 4/7 | X: 1111, Y: 1110, Z: 0000 | X1 Y1 X2 Y2 X3 Y3 X4 |
| 5/7 | X: 11111, Y: 01010, Z: 00000 | X1 X2 Y2 X3 X4 Y4 X5 |
| 6/7 | X: 011101, Y: 110010, | Y1 X2 Y2 X3 X4 Y5 X6 |
| | Z: 000000 | |
| 8/9 | X: 11111111, Y: 10000000, | X1 Y1 X2 X3 X4 X5 X6 X7 |
| | Z: 00000000 | |

In Table 1, “X”, “Y” and “Z” denote outputs of coded data x, y and z, respectively. In the puncturing pattern of Table 1, “1” indicates an output bit, and “0” indicates an omitted bit (bit not to be output). Further, the output sequence represents the sequence in which bits are output from bit strings of the coded data x, y and z.

The puncturing results in FIG. 7, and the puncturing table in Table 1 are merely illustrative, and the present invention is not limited thereto, but may employ other types of puncturing results. Further, the above-presented code rates should not be construed as limiting the present invention, and other code rates may be used according to embodiments.

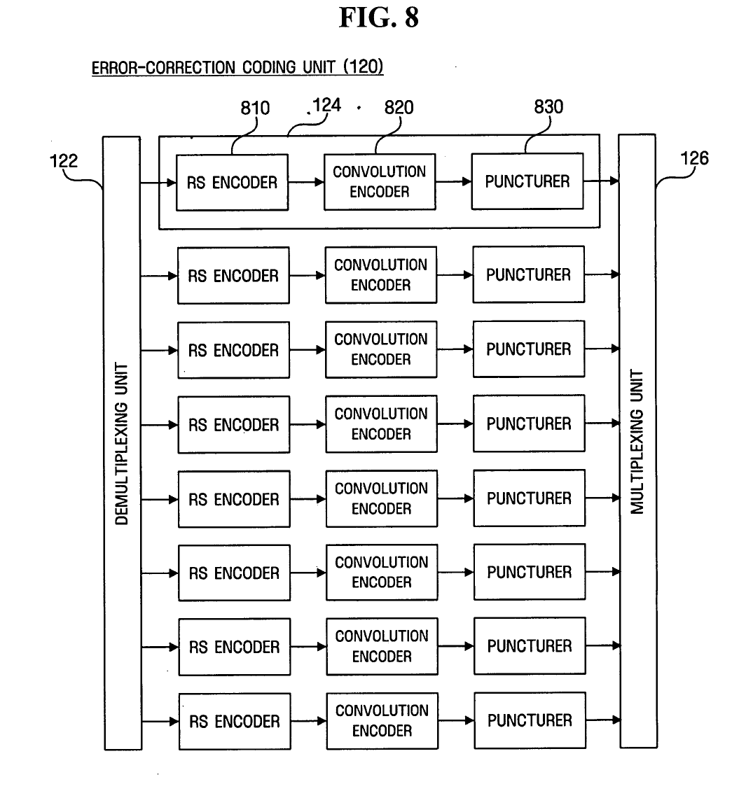

Through combinations of the outer encoder 410 and the inner encoder 420 as described above, it is possible to configure the error-correction coding unit 120 in various manners. FIG. 8 illustrates an error-correction coding unit 120 according to an exemplary embodiment of the present invention. Each sub error-correction coding unit 124, which constitutes the error-correction coding unit 120 illustrated in FIG. 8, includes an RS encoder 810, a convolution encoder 820 and a puncturer 830. The RS encoder 810 performs RS encoding for a data group input from the demultiplexing unit 122, and the convolution encoder 820 performs convolution encoding for the RS encoded data group. The puncturer 830 then performs puncturing for data output from the convolution encoder such that a code rate is adjusted to a predetermined code rate. Details of the convolution encoder 820 and the puncturer 830 have been already described with reference to FIGS. 5 to 7. Here, the respective sub error-correction coding units 124 may use the same code rate all together or may use different code rates. It is also possible for a part of the sub error-correction coding units 124 to use the same code rate.

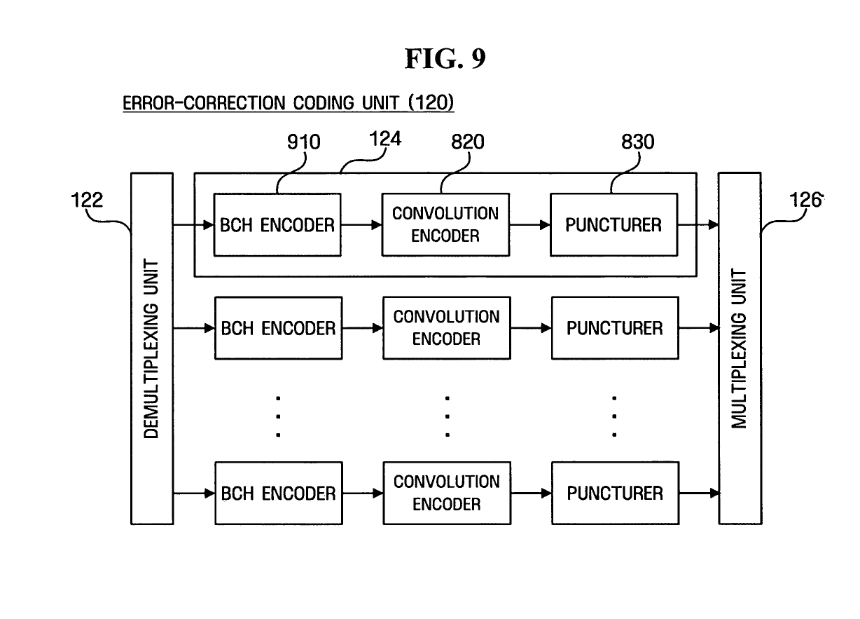

Although the RS encoder is used as the outer encoder in the embodiment of FIG. 8, the present invention is not limited thereto. For example, as illustrated in FIG. 9, it possible to implement an error-correction coding unit 120 which uses a BCH encoder 910 in place of the RS encoder. Further, other types of outer encoders than the RS encoder or the BCH encoder may also be used.

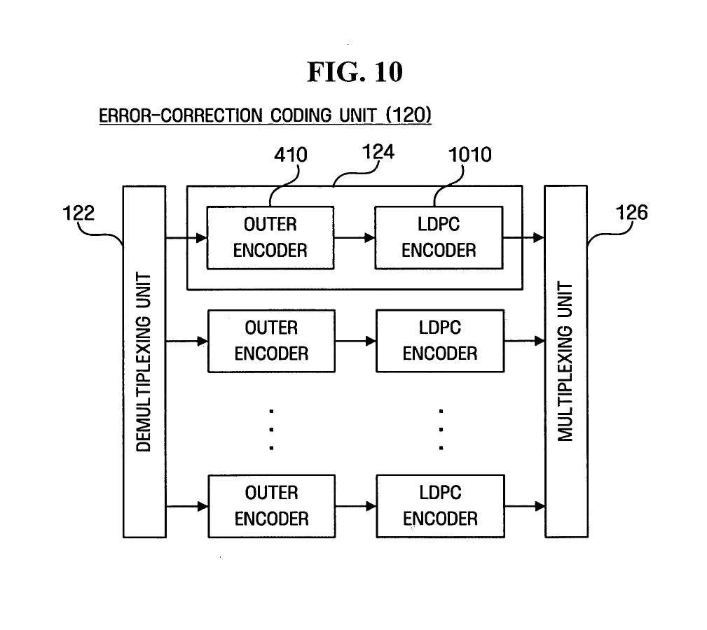

FIG. 10 illustrates an error-correction coding unit 120 according to another exemplary embodiment of the present invention. In the error-correction coding unit 120 illustrated in the drawing, each sub error-correction coding unit 124 includes an outer encoder 410 and a low-density parity check (LDPC) encoder 1010. The outer encoder 410 performs outer encoding for a data group input from the demultiplexing unit 122, and the LDPC encoder 1010 performs LDPC encoding for the outer encoded data group. Here, the above-mentioned RS encoder or BCH encoder may be used as the outer encoder 410. Also, the LDPC 1010 encoder may have a code rate of 1/3, 2/3 or 1/2. Of course, the present invention is not limited thereto, and the LDPC encoder 1010 may use other code rates.

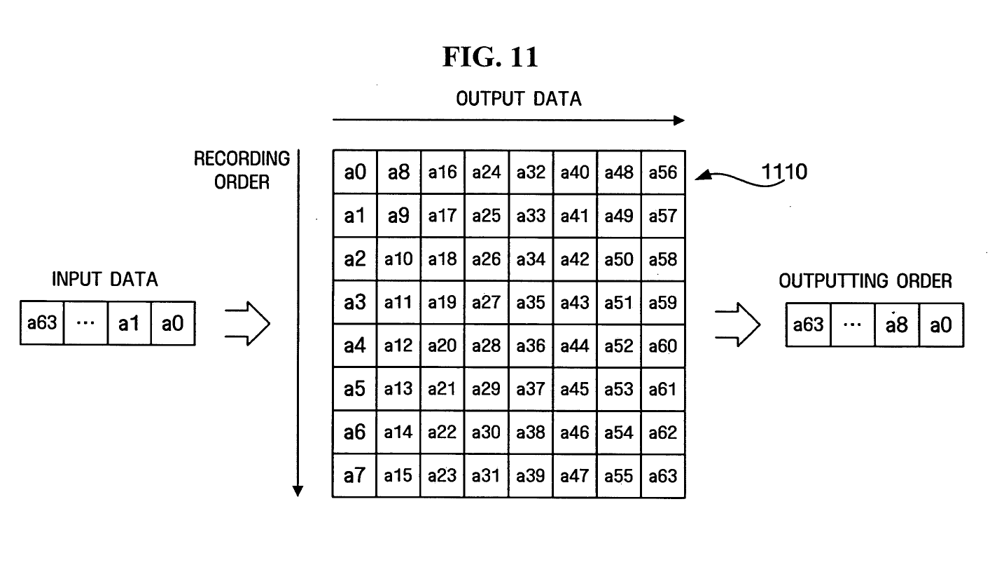

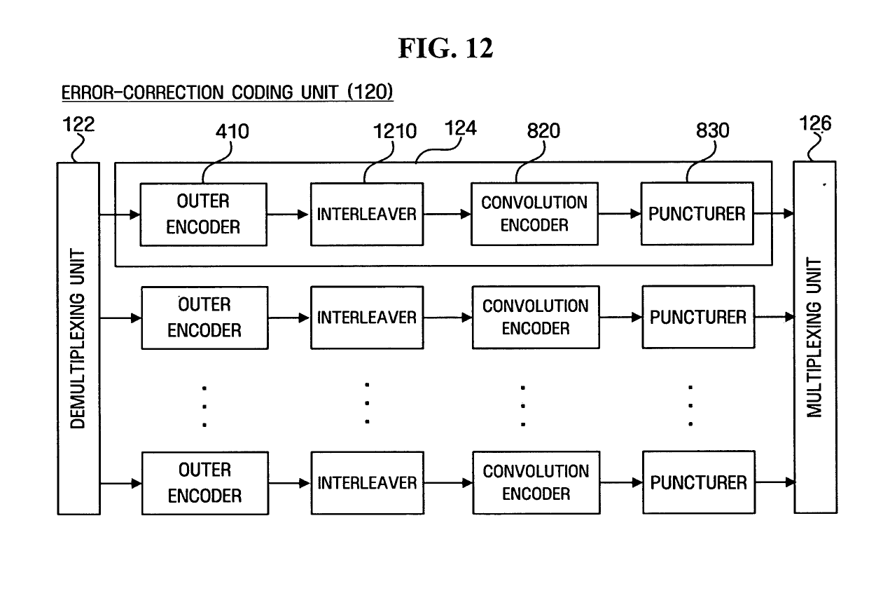

When the outer and inner encoders 410, 420 are used together for implementing the error-correction coding unit 120, an interleaver may be interposed between the outer encoder 410 and the inner encoder 420. The interleaves permutes the bit sequence of input data to output data having a new bit sequence. For example, as illustrated in FIG. 11, the interleaver records respective bits of input data in units of rows in a specified memory 1110, and then outputs the recorded bits in units of columns, if a certain number of bits are recorded, thereby permuting the bit sequence of output data. An example of an error-correction coding unit 120 including such an interleaver is illustrated in FIG. 12.

The error-correction coding unit 120 illustrated in FIG. 12 includes a plurality of sub error-correction coding units 124, and each sub error-correction coding unit 124 includes an outer encoder 410, an interleaver 1210, a convolution encoder 820 and a puncturer 830. In the error-correction coding unit 120 illustrated in the drawing, the interleaver 1210 interleaves data encoded in the outer encoder 410, and then the convolution encoder 920 and the puncturer 830 further processes the interleaved data. In the case of using the interleaver 1210, an error correction effect can be enhanced because the bit sequence of data encoded in the outer encoder 410 is distributed.

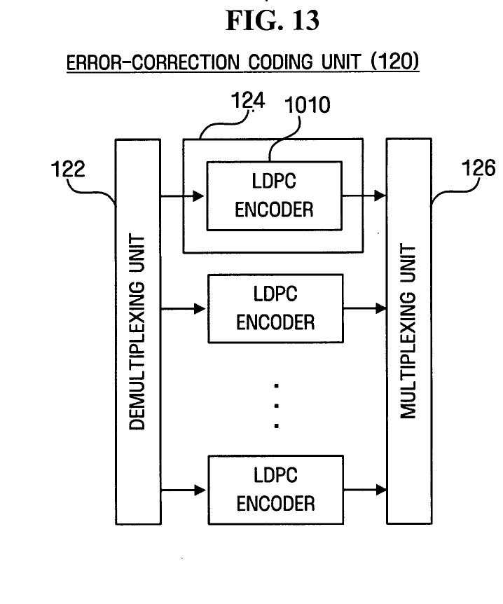

Although the error-correction coding unit 120 has been described through the above-mentioned embodiments that exemplify a case where a sub error-correction coding unit 124 constituting the error-correction coding unit 120 includes an outer encoder 410 and an inner encoder 420, the present invention is not limited thereto. For example, as illustrated in FIG. 13, a sub error-correction coding unit 124 according to an exemplary embodiment of the present invention may include only an LDPC encoder 1010. Of course, it is also possible to implement a sub error-correction coding unit 124 including a convolution encoder 820 and a puncturer 830. Further, a sub error-correction coding unit 124 including only an outer encoder 410 such as an RS encoder 810 or a BCH encoder 820 may be implemented.

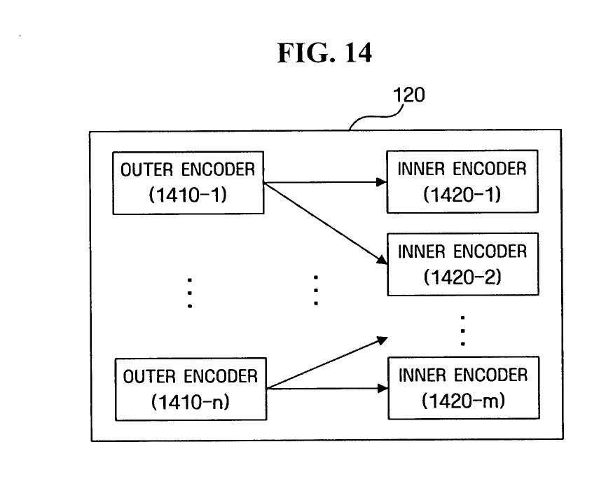

In the above-mentioned embodiments, the error-correction coding unit 120 has been described as being implemented such that the outer encoders 410 correspond one-to-one to the inner encoders 420, but the present invention is not limited thereto. For example, as illustrated in FIG. 14, an error-correction coding unit 120 according to an exemplary embodiment of the present invention may include n outer encoders 1410-1 to 1410-n and m inner encoders 1420-1 to 1420-m. Here, it should be noted that the embodiment of FIG. 4 is implemented if n is equal to m. However, if n is smaller than m, a plurality of inner encoders process data encoded in one outer encoder. That is, according to an exemplary embodiment of the present invention, it is possible to implement the error-correction coding unit 120 in such a manner that the number of outer encoders is smaller than that of inner encoders. Since the operation capacity of an inner encoder is commonly greater than that of an outer encoder, the time required for the overall error-correction coding is hardly wasted. The number of outer encoders and the number of inner encoders may be determined in various ratios depending on the operation performance of each encoder or performance of a radio-transmitting apparatus 100 to be implemented.

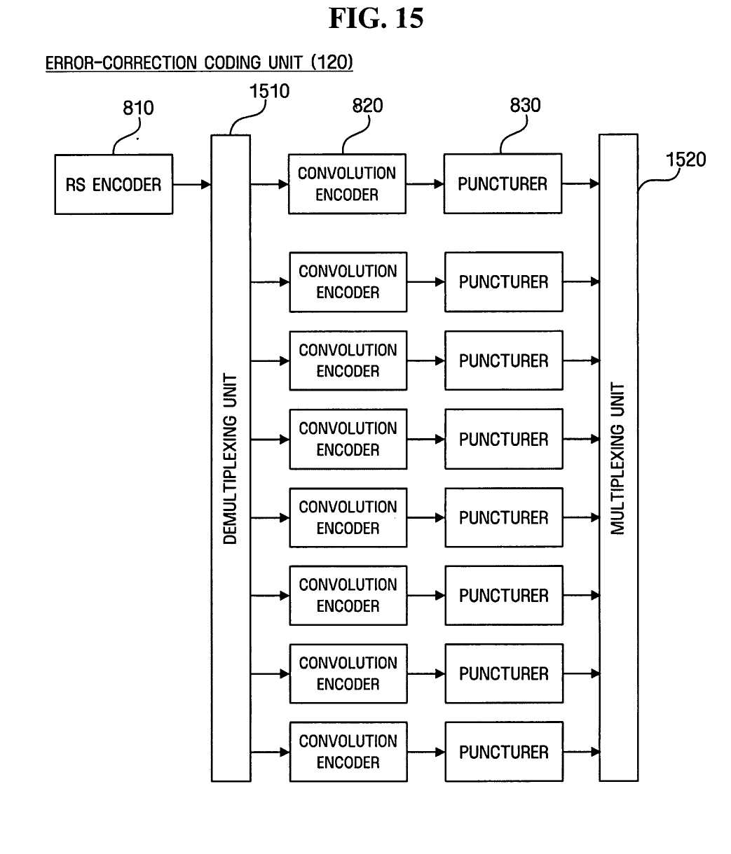

FIG. 15 illustrates an error-correction coding unit 120 according to an exemplary embodiment of the present invention. The error-correction coding unit 120 illustrated in the drawing includes one RS encoder 810, a demultiplexing unit 1510 splitting data processed by the RS encoder 810 into a plurality of data groups, convolution encoders 820 performing convolution coding for the respective data groups, puncturers 830 adjusting the code rate of convolution encoded data, and a multiplexing unit 1520 combining the punctured data groups. In the embodiment of FIG. 15, the RS encoder 810 is used in common for all input data, and the respective convolution encoders 820 dividedly process the data groups split by the demultiplexing unit 1510.

From the exemplary embodiments described with reference to FIGS. 4 to 15, other various embodiments of an error-correction coding unit 120 capable of performing in parallel error-correction processing operations for input data can be inferred, and such other embodiments should also be considered as embodiments of the present invention.

Referring to FIG. 1, the radio-transmitting unit 130 performs predetermined signal processing operations for error-correction coded data, and then outputs the resultant data. To this end, the radio-transmitting unit 130 includes a bit interleaver 131, a symbol interleaver 132, a Quadrature Amplitude Modulation (QAM) mapper 13, a pilot insertion unit 134, a Orthogonal Frequency Division Multiplexing (OFDM) modulation unit 135, a guard interval insertion unit 136, a digital-to-analog (D/A) converter 137 and an RF-processing unit 138.

The bit interleaver 131 and the symbol interleaver 132 interleave data encoded by the error-correction coding unit 120. The block sizes of the bit interleaver 131 and the symbol interleavers 132 are determined by the number of bits contained in one OFDM symbol. Similar to the interleaver described with reference to FIG. 11, the bit interleaver 131 and the symbol interleaver 132 serve to distribute a bit sequence, only the bit interleaver 131 performs interleaving on a bit-by-bit basis, and the symbol interleaver 132 performs interleaving on a symbol-by-symbol basis. Through the bit interleaver 131 and the symbol interleaver 132, adjacent bits of input data can be mapped to different non-adjacent sub-carriers, and can be alternately mapped to MSB (More Significant Bits) and LSB (Less Significant Bits) of a constellation.

When data is processed by the bit interleaver 131 and the symbol interleaver 132, even if burst errors occur, the burst errors can be changed to random errors by the receiver by a deinterleaving operation.

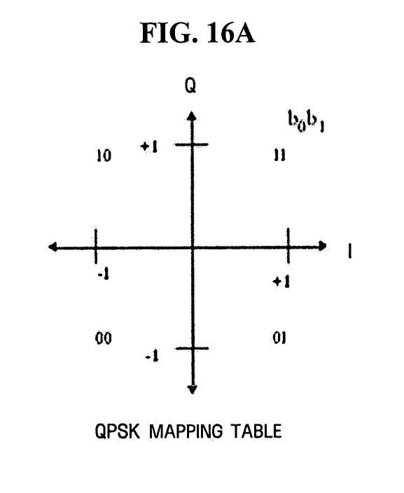

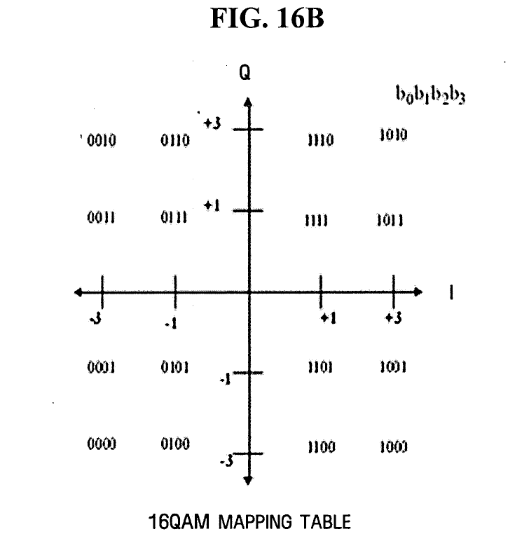

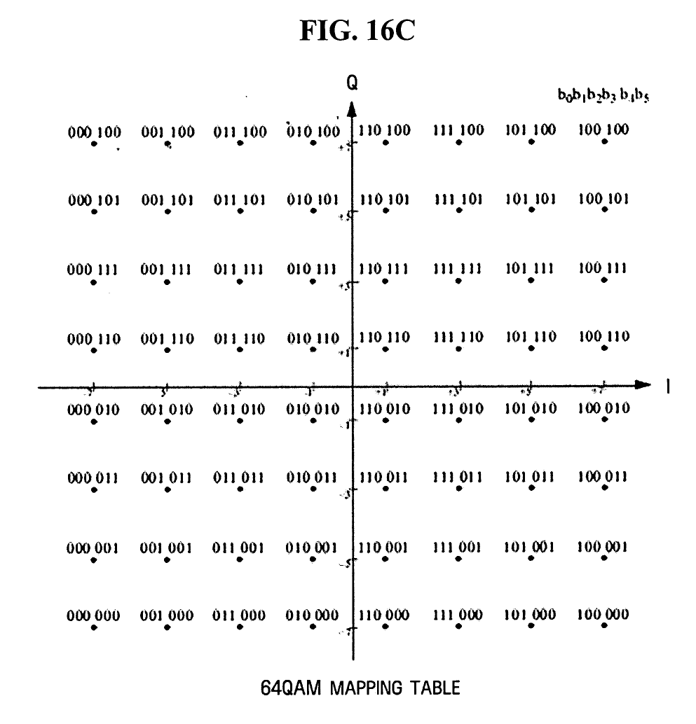

The QAM mapper 133 performs a symbol mapping operation by modulating interleaved data in a QAM modulation scheme. Here, QPSK (Quadrature Phase Shift Keying), 16 QAM (16 Quadrature Amplitude Modulation), 64 QAM (64 Quadrature Amplitude Modulation) or the like may be used as the QAM modulation scheme. An exemplary embodiment of a QAM mapping table, which the QAM mapper 133 uses according to the respective modulation schemes, is illustrated in FIGS. 16A to 16C. In symbol mapping, every certain number of bits of data are mapped to one point on any one of constellations illustrated in FIGS. 16A to 16B. Which constellation is used depends on which modulation scheme the QAM mapper 133 employs. As illustrated in FIGS. 16A to 16C, one symbol is determined every two bits of input data when the modulation scheme is QPSK, one symbol is determined every four bits of input data when the modulation scheme is 16 QAM, and one symbol is determined every six bits of input data when the modulation scheme is 64 QAM.

The pilot insertion unit 134 inserts pilots into input data. The pilots may used for frequency synchronization, clock synchronization, channel estimation and so forth.

The OFDM modulation unit 135 performs OFDM modulation for data into which pilots are inserted. In the OFDM modulation operation, input data is classified into N parallelized M-ary data symbols, and the classified data symbols are modulated through sub-carriers corresponding thereto, respectively. The results of modulation through the sub-carriers are added to constitute one OFDM symbol. The sub-carriers maintain their mutual orthogonality.

The guard interval insertion unit 136 inserts a guard interval into OFDM modulated data. The guard interval serves to solve a problem of Inter-Symbol Interference (ISI) or Inter-Carrier Interference (ICI).

OFDM symbol parameters, which the pilot insertion unit 134, the OFDM modulation unit 135 and the guard interval insertion unit 136 may use for high speed data transmission, are shown in Table 2 by way of example.

TABLE 2

| Parameter | Value |
|---|---|
| Data bandwidth | 1.73 |
| Minimum sampling rate (fₛ) | 2.508 Gsamples/s |
| No. of sub-carriers, N_{sc} | 512 |
| FFT period (T_{FFT}) | N_{sc}/fₛ − 204.15 ns |
| Sub-carrier spacing | 1/T_{FFT} − 4.898 |
| Guard interval, T_{GI} | 64/fₛ − 25.6 ns |
| Symbol duration | (T_{FFT} + T_{GI}) − 229.7 ns |
| No. of data sub-carriers | 336 |
| No. of DC sub-carriers | 3 |
| No. of pilots | 16 |
| No. of null sub-carriers | 157 |

The D/A converter 137 coverts digital data, into which the guard interval is inserted, into analog data, and the RF-processing unit 138 performs RF up-conversion for the analog data delivered from the D/A converter 137, and transmits the RF up-converted analog data over a wireless medium.

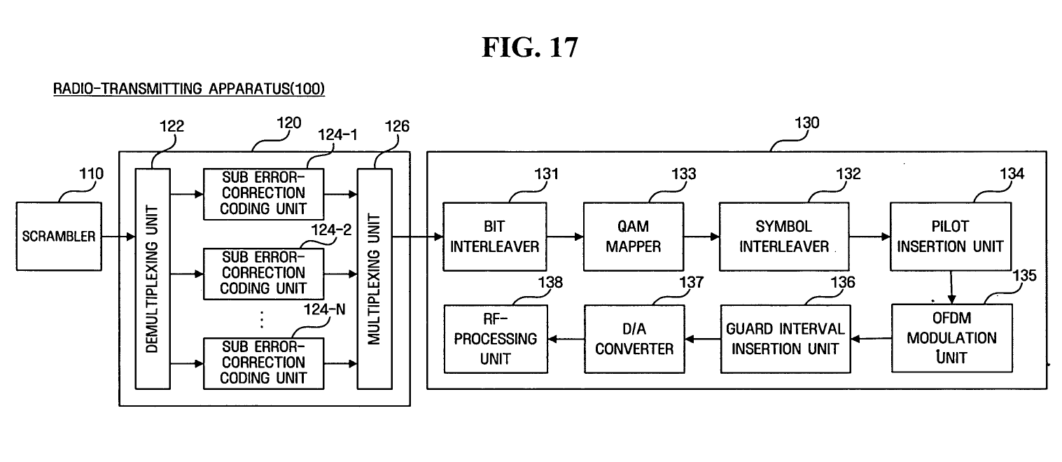

The structure of the radio-transmitting unit 130 in the radio-transmitting apparatus 100 described with reference to FIG. 1 is merely illustrative, and the present invention is not limited thereto. For example, as illustrated in FIG. 17, a radio-transmitting apparatus 100 according to another exemplary embodiment of the present invention may have a structure in which data passing through the QAM mapper 133 is delivered to and processed by the symbol interleaver 132. In addition, other types of signal-processing blocks necessary for radio data transmission may be further included as constituents of the radio-transmitting apparatus 100.

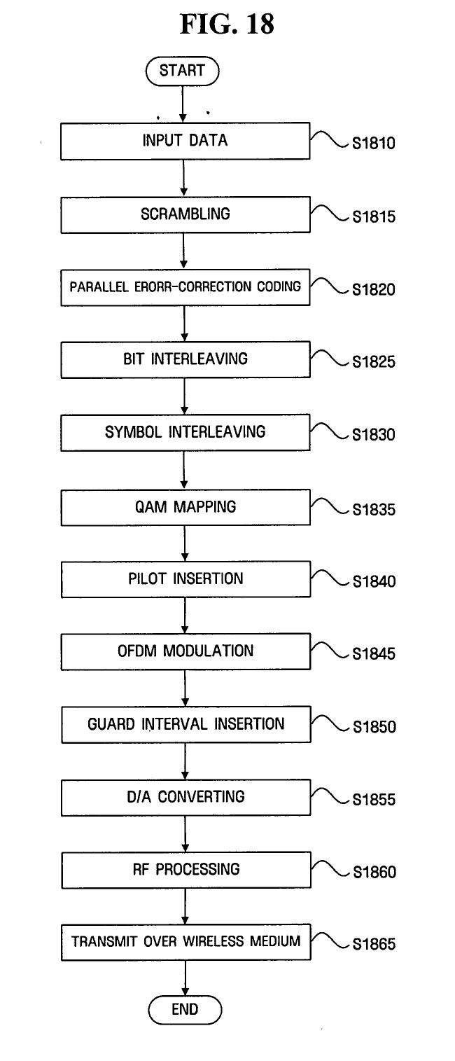

FIG. 18 illustrates a flowchart of radio-transmitting method for high speed data transmission according to an exemplary embodiment of the present invention. The flowchart illustrated in the drawing corresponds to an operational procedure of the radio-transmitting apparatus 100 described with reference to FIG. 1.

First, if data to be transmitted is input (S1810), the scrambler 110 scrambles the input data (S1815). Next, the error-correction coding unit 120 performs error-correction coding of the scrambled data in parallel (S1820). For the parallel error-correction coding, it may be preferable that the input data is divided in advance into data groups sized suitably for independent error-correction coding operations. In this way, the error-correction coding unit 120 can split the input data into the data groups, and perform error-correction coding operations independently for the respective data groups. Here, the error-correction coding operation is preferably based on FEC coding. The types of error-correction coding for the respective data groups have been already described above.

The error-correction coded data is subjected to a series of processing operations while passing through the radio-transmitting unit 130. The bit interleaver 131 and the symbol interleaver 132 perform interleaving for data processed by the error-correction coding unit 120 (S1825 and S1830), and the QAM mapper 133 performs symbol mapping for the interleaved data (S1835). Of course, it is also possible that the QAM mapper 133 processes data interleaved by the bit interleaver 131, and then the symbol interleaver 132 interleaves the data processed by the QAM mapper 133.

The pilot insertion unit 134 inserts pilots into data delivered from the QAM mapper 133 S1840, and the OFDM modulation unit 135 modulates (OFDM modulates) the data, into which the pilots are inserted, through a plurality of sub-carriers (S1845).

The resultant data of the OFDM modulation is delivered to the guard interval insertion unit 136, the guard interval insertion unit 136 inserts a guard interval into the delivered data (S1850), and then the D/A converter 137 converts the data into analog data (S1855).

Finally, the RF-processing unit 138 performs RF up-conversion for the analog data delivered from the D/A converter 137 (S1860), and transmits the RF up-converted analog data over a wireless medium (S1865).

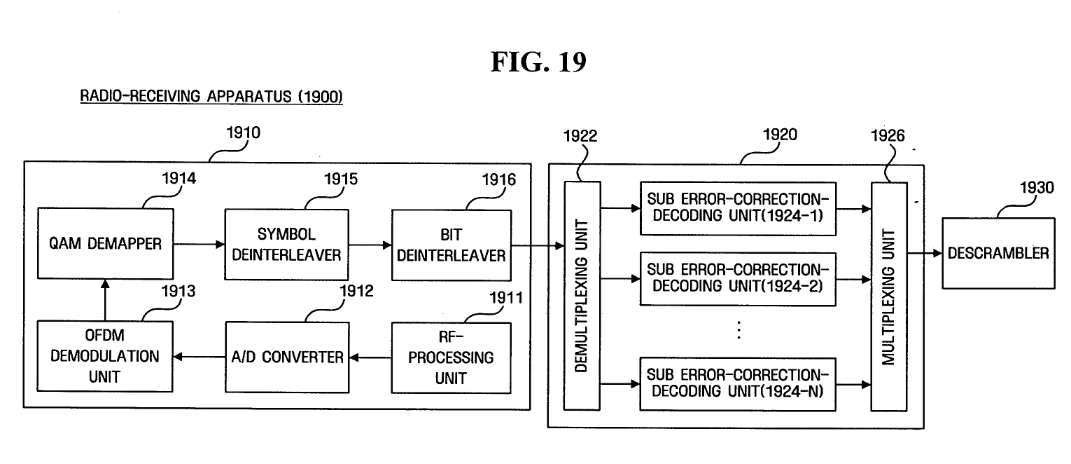

FIG. 19 illustrates a radio-receiving apparatus 1900 according to an exemplary embodiment of the present invention. The radio-receiving apparatus 1900 illustrated in the drawing includes a radio-receiving unit 1910, an error-correction-decoding unit 1920 and a descrambler 1930.

The radio-receiving unit 1910 processes a signal received over a wireless medium. To this end, the radio-receiving unit 1910 includes an RF-processing unit 1911, an A/D converter 1912, an OFDM demodulation unit 1913, a QAM demapper 1914, a symbol deinterleaver 1915 and bit deinterleaver 1916. The operations and functionalities of the respective components constituting the radio-receiving unit 1910 correspond to those of the respective components constituting the radio-transmitting unit 130 of the radio-transmitting apparatus 100 described with reference to FIG. 1, so a detailed description thereof will be omitted. In the case of using the radio-transmitting apparatus illustrated in FIG. 17, in which data is processed in sequence by the bit interleaver 131, the QAM mapper 133 and the symbol interleaver 132, the radio-receiving apparatus 1900 in FIG. 19 may be modified in such a manner that the QAM demapper 1914 and the symbol deinterleaver 1915 process data in reverse order.

The error-correction-decoding unit 1920 performs in parallel error correction decoding for input data. To this end, the error-correction-decoding unit 1920 includes a demultiplexing unit 1922 splitting input data into a plurality of data groups, a plurality of sub error-correction-decoding units 1924-1 to 1924-N performing error correction decoding operations for the respective data groups, and a multiplexing unit 1930 combining the error correction decoded data groups into serial decoded data. Hereinafter, the sub error-correction-decoding units 1924-1 to 1924-N will be designated by reference numeral “1924”.

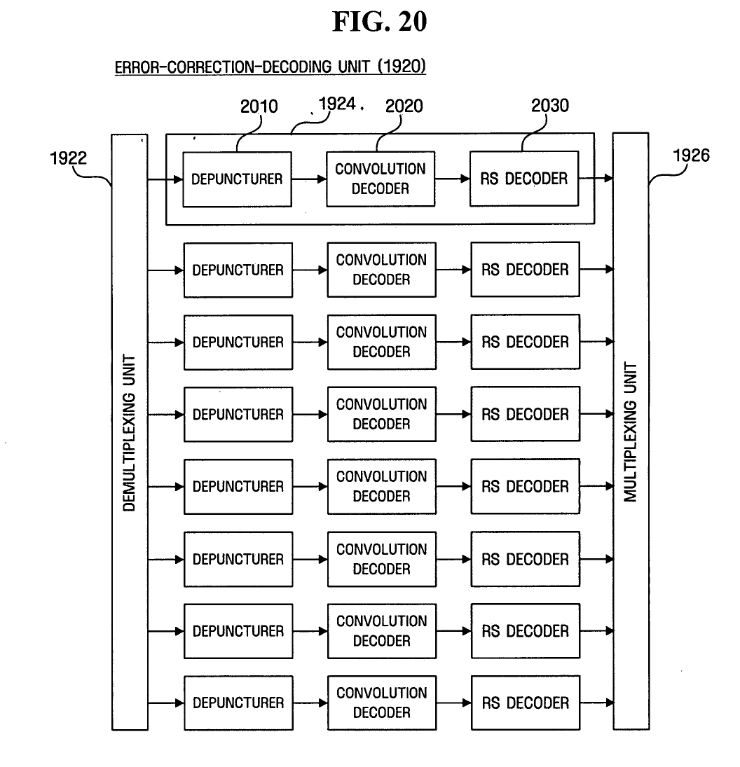

The error-correction-decoding unit may be designed such that it has a structure corresponding to that of an error-correction coding unit 120 used in the radio-transmitting apparatus 100. As an example, when an error-correction coding unit 120 is configured as illustrated in FIG. 8, an error-correction-decoding unit 1920 corresponding thereto may be configured as illustrated in FIG. 20.

In the error-correction-decoding unit 1920 illustrated in FIG. 20, each sub error-correction-decoding unit 1924 includes a depuncturer 2010, a convolution decoder 2020 and an RS decoder 2030. The depuncturer 2010 generates omitted bits of input data and annexes the generated bits to the input data, and the convolution decoder 2020 performs convolution decoding for the data processed by the depuncturer 2010. A Viterbi algorithm may be used for the convolution decoding. Of course, the present invention is not limited thereto, but may use other algorithms. The data processed by the convolution decoder 2020 is RS decoded by the RS decoder 2030. If an RS encoding rate is RS(N, K), erroneous parts can be restored when the number of errors occurring in data input into the RS decoder 2030 is less than (N−K)/2.

Referring to FIG. 19, the descrambler 1930 descrambles data delivered from the error-correction-decoding unit 1930.

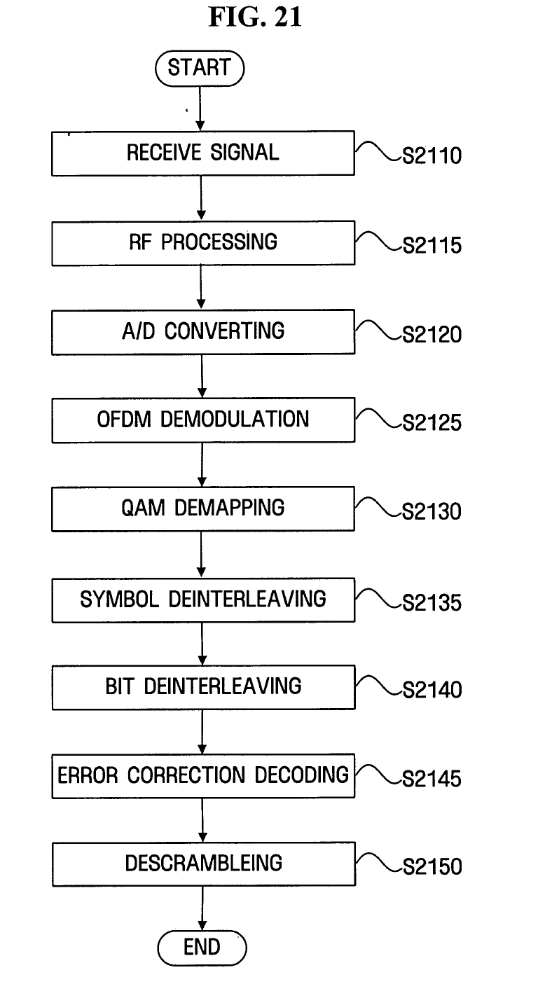

FIG. 21 illustrates a flowchart of a radio receiving method for high speed data transmission. The flowchart illustrated in the drawing corresponds to an operational procedure of the radio-receiving apparatus described with reference to FIG. 19.

If a signal transmitted over a wireless medium is received (S2110), the RF-processing unit 1911 performs RF down-conversion for the received signal (S2115), and the A/D converter 1912 converts analog data delivered from the RF-processing unit 1911 into digital data (S2120).

Next, the OFDM demodulation unit 1913 performs OFDM demodulation for the analog data delivered from the A/D converter 1912 (S2125). The demodulated data is QAM demapped (symbol demapped) by the QAM demapper 1914 (S2130). Here, a bit string corresponding to respective symbols constituting the demodulated data may be output from the QAM demapper 1914.

Data delivered from the QAM demapper 1914 is rearranged into the original bit sequence by the bit deinterleaver 1915 and the symbol deinterleaver 1916. Of course, when the processing order of the QAM demapper 1914 and the symbol deinterleaver 1915 is reversed in FIG. 19, the data delivered from the QAM demapper 1914 is processed in sequence by the symbol deinterleaver 1915, the QAM demapper 1914 and the bit deinterleaver 1916.

The error-correction-decoding unit 1920 performs in parallel error correction decoding for data delivered from the bit deinterleaver 1916 (S2145). In performing the error correction decoding, the error-correction-decoding unit 1920 may split input data into a plurality of data groups, and perform error correction decoding operations independently for the respective data groups.

Finally, the descrambler 1930 descrambles the error correction decoded data S2150.

In the foregoing, each component constituting the radio-transmitting apparatus 100 and the radio-receiving apparatus may be implemented as a kind of module. Herein, the term “module” means a software component or a hardware component such as a Field Programmable Gate Array (FPGA) or an Application Specific Integrated Circuit (ASIC), which performs certain tasks, but is not limited to software or hardware. A module may be so configured as to reside in an addressable storage medium or may be so configured as to be executed one or more processors. Thus, a module may include, by way of example, components such as software components, object-oriented software components, class components and task components, processes, functions, attributes, procedures, subroutines, segments of program codes, drivers, firmware, microcode, circuitry, data, databases, data architectures, tables, arrays, and variables. The functionality provided by the components and modules may be incorporated into fewer components and modules or may be further separated into additional components and modules.

According to the invention described above, one or more of the following effects may be obtained:

First, the time required for error-correction coding can be reduced.

Second, it is possible to transmit data at high speed.

Although exemplary embodiments of the present invention have been described for illustrative purposes, those skilled in the art will appreciate that various modifications, additions and substitutions are possible, without departing from the essential features and the scope and spirit of the invention as disclosed in the accompanying claims. Therefore, it should be appreciated that the exemplary embodiments described above are not limitative, but illustrative.

What is claimed is:

1. An apparatus for high speed data transmission, the apparatus comprising:
an error-correction coding unit which performs error-correction coding of input data in parallel; and
a radio-transmitting unit which processes the input data which has been error-correction coded and outputs the input data which has been processed to a wireless medium.

2. The apparatus of claim 1, further comprising a scrambler which scrambles the input data and provides the input data which has been scrambled to the error-correction coding unit.

3. The apparatus of claim 1, wherein the error-correction coding unit comprises a plurality of sub error-correction coding units which perform error-correction coding independently for respective data groups split from the input data.

4. The apparatus of claim 3, wherein the error-correction coding unit further comprises:
a demultiplexing unit which splits the data into the plurality of data groups; and
a multiplexing unit which combines the plurality of data groups error-correction coded by the error-correction coding unit.

5. The apparatus of claim 3, wherein the plurality of sub error-correction coding units perform forward error correction.

6. The apparatus of claim 3, wherein a number of the plurality of sub error-correction coding units is one of 2, 4, 6, 8, 10, 12 and 16.

7. The apparatus of claim 3, wherein the plurality of sub error-correction coding units use a same code rate.

8. The apparatus of claim 3, wherein the plurality of sub error-correction coding units use different code rates or overlapping code rates.

9. The apparatus of claim 3, wherein each of the plurality of sub error-correction coding units comprises:
an outer encoder which performs outer encoding on a data group of the plurality of data groups; and
an inner encoder which performs inner encoding on the data group which has been outer encoded by the outer coder.

10. The apparatus of claim 9, wherein the outer encoder comprises one of a Reed-Solomon (RS) encoder which performs RS encoding and a Bose-Chaudhuri-Hocquenghem (BCH) encoder which performs BCH encoding.

11. The apparatus of claim 9, wherein the inner encoder comprises:
a convolution encoder which performs convolution encoding of the data group which has been outer encoded by the outer coder; and
a puncturer which adjusts a code rate of the data group which has been convolution encoded by the convolution encoder.

12. The apparatus of claim 11, wherein the code rate is one of 1/3, 1/2, 2/3, 3/4, 4/5, 4/7, 3/5, 5/7, 6/7 and 8/9.

13. The apparatus of claim 9, further comprising an interleaver which interleaves the data group which has been outer encoded by the outer encoder, wherein the convolution encoder performs convolution encoding on the data group which has been interleaved by the interleaver.

14. The apparatus of claim 3, wherein each of the plurality of sub error-correction coding units comprises:
an outer encoder which performs outer encoding for a data group of the plurality of data groups; and
a low density parity check (LDPC) encoder which performs LDPC encoding of the data group which has been outer encoded by the outer encoder.

15. The apparatus of claim 14, wherein the outer encoder comprises one of a Reed-Solomon (RS) encoder which performs RS encoding and a Bose-Chaudhuri-Hocquenghem (BCH) encoder which performs BCH encoding.

16. The apparatus of claim 14, wherein a code rate of the LDPC encoder is one of 1/3, 2/3 and 1/2.

17. The apparatus of claim 3, wherein each of the plurality of sub error-correction coding units comprises at least one of an outer encoder which performs outer encoding and an inner encoder which performs inner encoding.

18. The apparatus of claim 3, wherein each of the plurality of sub error-correction coding units comprises a low density parity check (LDPC) encoder which performs LDPC encoding.

19. The apparatus of claim 1, wherein the error-correction coding unit comprises:
at least one outer encoder which performs outer encoding on at least one data group of a plurality of data groups constituting the input data; and
a plurality of inner encoders which performs inner encoding of the at least one data group which has been outer encoded by the at least one outer encoder.

20. The apparatus of claim 19, wherein a number of the at least one outer encoder is equal to or smaller than a number of the plurality of inner encoders.

21. The apparatus of claim 1, wherein the error-correction coding unit comprises:
a Reed-Solomon (RS) encoder which performs RS encoding of a plurality of data groups constituting the input data; and
a plurality of inner encoders which performs inner encoding of at least one data group of the plurality of data groups which have been RS encoded by the RS encoder.

22. The apparatus of claim 21, wherein each of the plurality of inner encoders comprises:
a convolution encoder which performs convolution encoding of at least one data group of the plurality of data groups which have been RS encoded by the RS encoder; and
a puncturer which adjusts a code rate of the at least one data group which has been convolution encoded by the convolution encoder.

23. An apparatus for error-correction coding, the apparatus comprising:
a demultiplexing unit which splits input data into a plurality of data groups; and
a plurality of sub error-correction coding units which perform error-correction coding independently for each of the plurality of data groups.

24. The apparatus of claim 23, further comprising a multiplexing unit which combines the plurality of data groups which have been error-correction coded by the plurality of sub error-correction coding units.

25. The apparatus of claim 23, wherein each of the plurality of sub error-correction coding units comprises:
an outer encoder which performs outer encoding for a data group of the plurality of data groups; and
an inner encoder which performs inner encoding of the data group which has been outer encoded by the outer encoder.

26. An apparatus for error-correction coding, the apparatus comprising:
at least one outer encoder which performs outer encoding of at least one data group constituting input data; and
a plurality of inner encoders which performs inner encoding of the at least one data group which has been outer encoded by the at least one outer encoder.

27. A method of high speed data transmission, the method comprising:
performing in parallel error-correction coding of input data; and
processing the input data which has been error-correction coded and outputting the input data which has been processed to a wireless medium.

28. The method of claim 27, further comprising scrambling the input data, wherein the performing the in parallel error-correction coding of the input data comprises performing the in parallel error-correction coding of the input data which has been scrambled.

29. The method of claim 27, wherein the performing of the error-correction coding comprises performing forward error correction.

30. The method of claim 27, wherein the performing the error-correction coding comprises performing error-correction coding independently for each of a plurality of data groups split from the input data.

31. The method of claim 30, further comprising:
splitting the first data into the plurality of data groups; and
combining the plurality of data groups which have been error-correction coded.

32. The method of claim 30, wherein a same code rate is applied to all of the plurality of data groups.

33. The method of claim 30, wherein different code rates or overlapping code rates are applied to each of the plurality of data groups.

34. The method of claim 30, wherein the performing the error-correction coding independently for each of the plurality of data groups comprises:
performing outer encoding independently for each of the plurality of data groups; and
performing inner encoding independently for each of the data groups which have been outer encoded.

35. The method of claim 34, wherein the outer encoding comprises one of Reed-Solomon encoding and Bose-Chaudhuri-Hocquenghem encoding.

36. The method of claim 34, wherein the performing the inner encoding comprises:
performing convolution encoding independently for each of the data groups which have been outer encoded; and
adjusting a code rate for each of the data groups which have been convolution encoded.

37. The method of claim 36, wherein the code rate is one of 1/3, 1/2, 2/3, 3/4, 4/5, 4/7, 3/5, 5/7, 6/7 and 8/9.

38. The method of claim 30, wherein the performing the error-correction coding independently for each of the plurality of data groups comprises:
performing outer encoding independently for each of the plurality of data groups; and
performing low density parity check (LDPC) encoding independently for each of the data groups which have been outer encoded.

39. The method of claim 38, wherein the outer encoding comprises one of Reed-Solomon encoding and Bose-Chaudhuri-Hocquenghem encoding.

40. The method of claim 38, wherein a code rate for the data groups which have been LDPC encoded is one of 1/3, 2/3 and 1/2.

41. The method of claim 30, wherein the performing the error-correction coding independently for each of the plurality of data groups comprises:
performing outer encoding independently for each of the plurality of data groups;
performing interleaving independently for each of the data groups which have been outer encoded; and
performing inner encoding independently for each of the data groups which have been interleaved.

42. The method of claim 30, wherein the performing the error-correction coding independently for each of the plurality of data groups comprises performing at least one of outer encoding and inner encoding independently for each of the plurality of data groups.

43. The method of claim 30, wherein the performing the error-correction coding independently for each of the plurality of data groups comprises performing low density parity check encoding independently for each of the plurality of data groups.

44. The method of claim 27, wherein the performing the error-correction coding comprises:
splitting the input data into a plurality of first data groups and performing outer encoding for each of the plurality of first data groups; and
splitting each of the data groups which have been outer encoded into a plurality of second data groups and performing inner encoding for each of the plurality of second data groups.

45. The method of claim 27, wherein the performing the error-correction coding comprises:
performing Reed-Solomon (RS) encoding for a plurality of data groups constituting the input data; and
performing inner encoding independently for each of the plurality of data groups which have been RS encoded.

46. The method of claim 45, wherein the performing the inner encoding comprises:
performing convolution encoding independently for each of the plurality of data groups which have been RS encoded; and
adjusting a code rate for each of the data groups which have been convolution encoded.

47. A method of error-correction coding, the method comprising:
splitting input data into a plurality of data groups; and
performing error-correction coding independently for each of the plurality of data groups.

48. The method of claim 47, which further comprises combining the plurality of data groups which have been error-correction coded.

49. The method of claim 47, wherein the performing the error-correction coding comprises:
performing outer encoding independently for each of the plurality of data groups; and
performing inner encoding independently for each of the data groups which have been outer encoded.

50. A method of error-correction coding, the method comprising:
splitting input data into a plurality of first data groups and performing outer encoding for each of the plurality of first data groups; and
splitting each of the first data groups which have been outer encoded into a plurality of second data groups and performing inner encoding for each of the plurality of second data groups.

51. A method of error-correction coding, the method comprising:
performing Reed-Solomon (RS) encoding for a plurality of data groups constituting input data; and
performing inner encoding independently for each of the plurality of data groups which have been RS encoded.

52. An apparatus for radio reception, the apparatus comprising:
a radio-receiving unit which extracts data from a signal received over a wireless medium; and
an error-correction-decoding unit which performs error correction decoding of the data in parallel.

53. A method of radio reception, the method comprising:
extracting data from a signal received over a wireless medium; and
performing error-correction decoding of the data in parallel.

54. An apparatus for error correction decoding, the apparatus comprising:
a demultiplexing unit which splits input data into a plurality of data groups; and
a plurality of error-correction-decoding units which perform error-correction decoding independently for each of the plurality of data groups.

55. A method of error correction decoding, the method comprising:
splitting input data into a plurality of data groups; and
performing error-correction decoding independently for each of the plurality of data groups.
